(19) United States
(12) Patent Application Publication
(10) Pub. No.: US 2019/0118654 A1
(43) Pub. Date: Apr. 25, 2019

(54) ELECTRIC-VEHICLE PROPULSION CONTROL APPARATUS

(71) Applicant: Mitsubishi Electric Corporation, Chiyoda-ku, Tokyo (JP)

(72) Inventors: Ryo Yokozutsumi, Tokyo (JP); Yasuhiro Shiraki, Tokyo (JP); Taichi Yoshida, Tokyo (JP)

(73) Assignee: Mitsubishi Electric Corporation, Chiyoda-ku, Tokyo (JP)

(21) Appl. No.: 16/099,334

(22) PCT Filed: May 27, 2016
(86) PCT No.: PCT/JP2016/065804

§ 371 Date: Nov. 6, 2018

(51) Int. Cl. B60L 3/00; H03H 7/01; H02P 27/06; H02P 29/50; H02M 1/12; H02M 7/537

(52) U.S. Cl. CPC B60L 3/00; H03H 7/0115; H02P 27/06; B60L 2200/26; H02M 1/126; H02M 7/537; H02P 29/50

(57) ABSTRACT

An electric-vehicle propulsion control apparatus includes a filter device and a power converter. The filter device is configured such that a first inductance element, a third inductance element, and a capacitor element are connected in series to constitute a series circuit, one end of the series circuit is electrically connected to low-potential-side power supply wiring connecting a rail and the power converter; the other end thereof is electrically connected to high-potential-side power supply wiring connecting an overhead line and the power converter; a second inductance element, provided between an electrical connection point of the other end of the series circuit and the overhead line, and the first inductance element are magnetically coupled; and the magnetic coupling generates mutual inductance having a positive value between the electrical connection point of the one end of the series circuit and the power converter.

### FIELD

The present invention relates to an electric-vehicle propulsion control apparatus that includes a filter device and a power converter.

### BACKGROUND

An electric-vehicle propulsion control apparatus includes a power converter that receives electric power supplied from a feeder and drives a motor using the received electric power. The power converter includes a conversion element therein. The switching operation of the conversion element of the power converter causes a return current containing a harmonic current to flow through the rail that is the return path to a substation serving as a power supply. Harmonic components contained in the return current can cause malfunctions in railroad safety equipment that includes crossing control devices and signals that are already installed. For this reason, there is sometimes a requirement to attenuate the harmonic components contained in the return current.

In view of the technical background as described above, the following Patent Literature 1 discloses a method for attenuating harmonic components over a relatively wide frequency range, i.e., around several hundred Hertz, of the harmonic components contained in the return current.

### CITATION LIST

### Patent Literature

Patent Literature 1: Japanese Patent Application Laid-open No. 2002-315101

### SUMMARY

### Technical Problem

As represented by the above Patent Literature 1, conventional techniques for attenuating harmonic components have focused on attenuating harmonic components over a wide frequency range rather than focusing on attenuation. For this reason, there is not sufficient attenuation to attenuate harmonic components in a relatively narrow frequency range in a particular frequency band, and therefore there is a demand for new techniques.

The present invention has been made in view of the above, and an object of the present invention is to provide an electric-vehicle propulsion control apparatus that includes a filter device that can ensure sufficient attenuation of harmonic components in a relatively narrow frequency range in a particular frequency band.

### Solution to Problem

In order to solve the above problem and achieve the object, an aspect of the present invention is an electric-vehicle propulsion control apparatus including: a filter device; and a power converter. The filter device is configured such that: a first inductance element and a capacitor element are connected in series to constitute a series circuit; one end of the series circuit is electrically connected to low-potential-side power supply wiring that connects a rail and the power converter; and another end of the series circuit is electrically connected to high-potential-side power supply wiring that connects an overhead line and the power converter. A second inductance element, which is provided between an electrical connection point of the another end of the series circuit and the overhead line, and the first inductance element are magnetically coupled to each other, and the magnetic coupling generates a mutual inductance having a positive value between the electrical connection point and the power converter.

### Advantageous Effects of Invention

According to the present invention, it is possible to ensure sufficient attenuation of harmonic components in a relatively narrow range in a particular frequency band.

### BRIEF DESCRIPTION OF DRAWINGS

FIG. 1 is a diagram illustrating the configuration of an entire electric-vehicle drive system that includes an electric-vehicle propulsion control apparatus according to a first embodiment.

FIG. 2 is an equivalent circuit diagram explaining the filter operation of the electric-vehicle propulsion control apparatus according to the first embodiment.

FIG. 3 is a diagram illustrating frequency characteristics of a return current according to the first embodiment.

FIG. 4 is a diagram illustrating the configuration of an electric-vehicle propulsion control apparatus according to a second embodiment.

### DESCRIPTION OF EMBODIMENTS

Hereinafter, an electric-vehicle propulsion control apparatus according to embodiments of the present invention is described in detail with reference to the drawings. Note that, the present invention is not limited to the following embodiments.

### First Embodiment

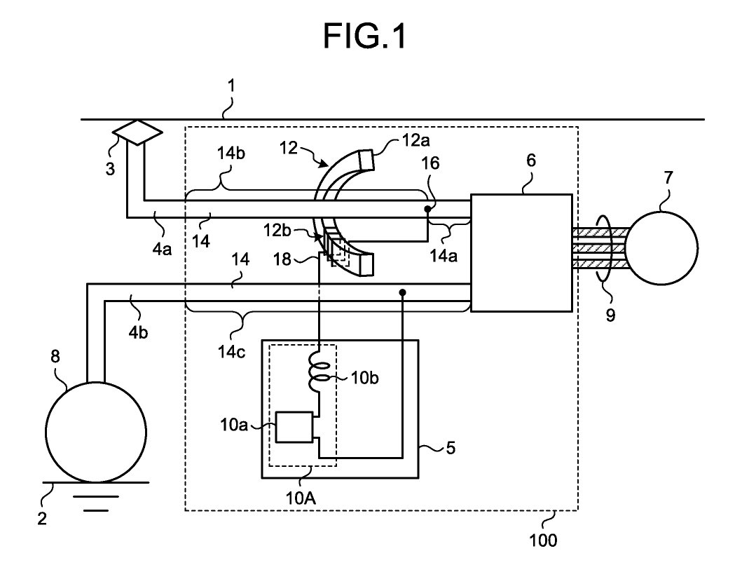

FIG. 1 is a diagram illustrating the configuration of an entire electric-vehicle drive system that includes an electric-vehicle propulsion control apparatus according to a first embodiment. In FIG. 1, an electric-vehicle propulsion control apparatus 100 according to the first embodiment includes, as main components, a filter circuit 5, a power converter 6, and a first reactor 12. The filter circuit 5 and the first reactor 12 constitute a filter device. The first reactor 12 includes a reactor core 12a and a winding portion 12b. The power converter 6 is connected to a motor 7 by a connection cable 9. The motor 7 is a three-phase motor, and it provides the propulsive force for an electric vehicle.

One end of the electric-vehicle propulsion control apparatus 100 is connected to an overhead line 1 via a high-potential-side feeder 4a and a current collector 3. The other end of the electric-vehicle propulsion control apparatus 100 is connected to a rail 2 via a low-potential-side feeder 4b and a wheel 8. A power supply cable 14 that electrically connects the feeders 4a and 4b and the power converter 6 is installed in the electric-vehicle propulsion control apparatus 100. With this configuration, DC power supplied from the overhead line 1 is supplied to the power converter 6 via the feeders 4a and 4b and the power supply cable 14. The power converter 6 converts DC voltage applied from the overhead line 1 into AC voltage having given frequency and voltage to drive the motor 7.

Next, the configuration of the filter device in the electric-vehicle propulsion control apparatus 100 according to the first embodiment is described.

A capacitor 10a and a second reactor 10b are connected in series to constitute a series circuit part 10A. One end of the series circuit part 10A is connected to a ground cable 14c, which is a low-potential-side power supply cable.

Furthermore, the electric wiring drawn out from the other end of the series circuit part 10A, i.e., a filter wire 18 of the filter circuit 5, is wound around the reactor core 12a to form the winding portion 12b of the first reactor 12. After forming the winding portion 12b, the filter wire 18 is connected to the high-potential-side power supply cable 14.

Here, if the point where the filter wire 18 is connected to the high-potential-side power supply cable 14 is a connection point 16, then the high-potential-side power supply cable 14 is divided, at the connection point 16, into two parts. One of the two parts is referred to as a cable first part 14a and the other is referred to as a cable second part 14b. Specifically, the cable first part 14a is the part installed between the connection point 16 and the power converter 6, and the cable second part 14b is the part installed between the connection point 16 and the end portion of the high-potential-side feeder 4a.

The reactor core 12a is made of a magnetic material. A suitable magnetic material is an amorphous, ferrite material, or a dust core obtained by finely crushing and solidifying iron. The reactor core 12a is formed in a semicircular shape and is disposed so as to cover the cable second part 14b. That is, the reactor core 12a is disposed so as to cover part of the power supply cable 14 on the side closer to the overhead line 1 than the connection point 16.

In the series circuit part 10A, the connection order of the capacitor 10a and the second reactor 10b may be reversed. Specifically, in the opposite way round to the drawing, one end of the capacitor 10a may be electrically connected to the high-potential-side power supply cable 14 via the first reactor 12 and one end of the second reactor 10b may be electrically connected to the low-potential-side power supply cable 14.

Here, there is an additional description of the first reactor 12. In the above description, the shape of the reactor core 12a has been described as a semicircular shape, but the shape of the reactor core 12a is not necessarily required to be a semicircular shape. The shape of the reactor core 12a may be any shape as long as the reactor core 12a does not completely cover the periphery of the cable second part 14b of the power supply cable 14. That is, as long as the reactor core 12a has an opening, the reactor core 12a of the present embodiment can be any shape.

Next, the winding direction of the winding portion 12b formed in the first reactor 12 is described. When a noise current flows through the cable first part 14a of the power supply cable 14, the noise current also flows into the winding portion 12b. The winding direction of the winding portion 12b is determined such that the magnetic flux (referred to as “first magnetic flux” for convenience) generated in the reactor core 12a by the noise current flowing through the cable first part 14a and the magnetic flux (referred to as “second magnetic flux” for convenience) generated in the reactor core 12a by the noise current flowing through the winding portion 12b cancel each other out. That is, the winding portion 12b is wound in a direction such that the first magnetic flux and the second magnetic flux generated in the reactor core 12a cancel each other out. In the winding portion 12b, it is preferable that the number of turns of the filter wire 18 being wound around the reactor core 12a is two or more. If the number of turns is two or more, it is easy to make the inductance of the first reactor 12 larger than the inductance of the second reactor 10b. When the inductance of the first reactor 12 is larger than the inductance of the second reactor 10b, the second reactor 10b may be omitted.

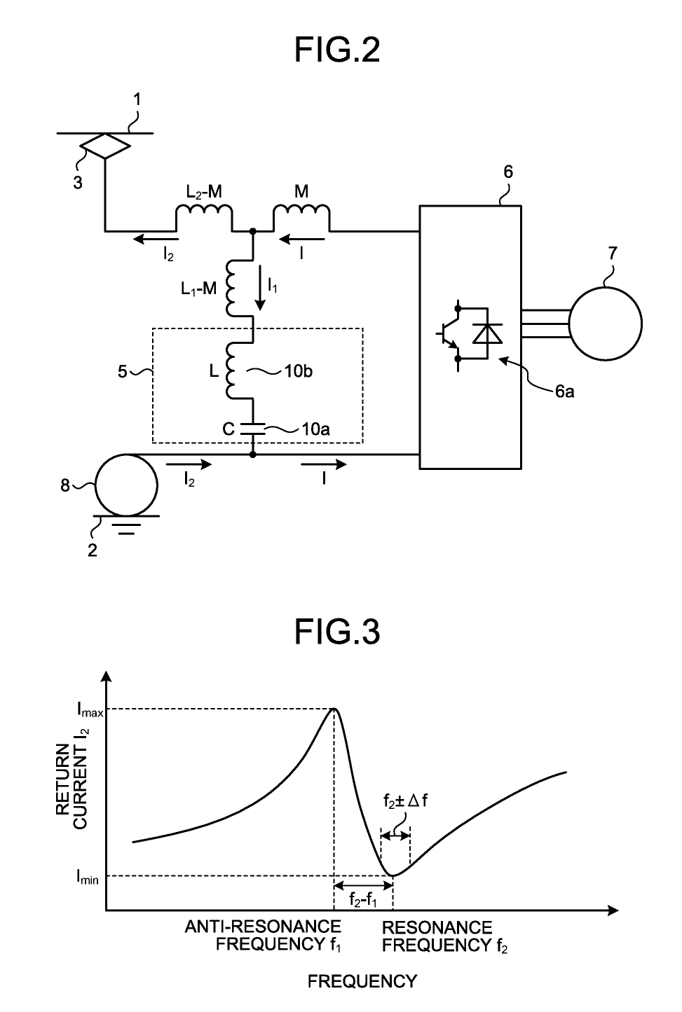

FIG. 2 is an equivalent circuit diagram explaining the filter operation of the electric-vehicle propulsion control apparatus 100 according to the first embodiment. In FIG. 2, the same components as those in FIG. 1 are denoted by the same reference signs.

As described above, the first magnetic flux generated in the reactor core 12a by the current flowing through the cable first part 14a and the second magnetic flux generated in the reactor core 12a by the current flowing through the filter wire 18 act in the directions such that they cancel each other out. For this reason, mutual inductance M occurs in the cable first part 14a in an electric circuit. Here, the polarity of the mutual inductance M is “positive”. Thus, if the self-inductance of the winding portion 12b is denoted by L₁, then the inductance generated in the winding portion 12b is L₁-M. In a similar manner, if the self-inductance of the cable second part 14b is denoted by L₂, then the inductance generated in the cable second part 14b is L₂-M. In addition, the capacitance of the capacitor 10a constituting the filter circuit 5 is denoted by C, and the inductance of the second reactor 10b is denoted by L. These constitute the equivalent circuit illustrated in FIG. 2. Because the self-inductance of the cable second part 14b is small compared with the mutual inductance M and is thus regarded as zero, the self-inductance of the cable first part 14a is not illustrated in the equivalent circuit in FIG. 2.

Next, with reference to FIGS. 2 and 3, the operation of the main components of the electric-vehicle propulsion control apparatus 100 according to the first embodiment is described. FIG. 3 is a diagram illustrating the frequency characteristics of a return current I₂ according to the first embodiment.

The power converter 6 includes a conversion element 6a therein. Due to the switching operation of the conversion element 6a, a noise current I flows through the power supply cable 14. The noise current I is divided into a filter circuit current I₁, which is a current component flowing toward the filter circuit 5, and a return current I₂, which is a current component flowing toward the overhead line 1. FIG. 3 illustrates the frequency characteristics of the return current I₂. In FIG. 3, the frequency at which the return current I₂ is maximum is referred to as an anti-resonance frequency, and it is denoted as f₁. The frequency at which the return current I₂ is minimum is referred to as a resonance frequency, and it is denoted as f₂.

As illustrated in FIG. 3, the anti-resonance frequency f₁ is a frequency at which the return current I₂ becomes a maximum value Iₘₐₓ. The return current I₂ becomes a maximum value when the filter circuit current I₁ becomes the smallest, i.e., when the mutual inductance M and the series circuit of the inductance L₁−M generated in the winding portion 12b, the capacitance C of the capacitor 10a, and the inductance L of the second reactor 10b cause parallel resonance. Thus, the anti-resonance frequency f₁ can be expressed by the following formula:

f₁=½π{√[M+(L₁−M)+L]·C}

=½π{√(L₁+L)·C} (1)

As illustrated in FIG. 3, the resonance frequency f₂ is a frequency at which the return current I₂ becomes a minimum value Iₘᵢₙ. The return current I₂ becomes a minimum value when the filter circuit current I₁ becomes the largest, i.e., when the inductance L₁−M generated in the winding portion 12b, the capacitance C of the capacitor 10a, and the inductance L of the second reactor 10b cause series resonance. Thus, the resonance frequency f₂ can be expressed by the following formula:

f₂=½π{√(L₁−M+L)·C} (2)

In FIG. 3, the frequency band in which it is desirable to ensure attenuation is the frequency band f₂±Δf around the resonance frequency f₂. Thus, by determining the circuit elements of the filter circuit 5 and the first reactor 12 in accordance with the frequency in the frequency band in which it is desirable to ensure attenuation, the desired filtering operation is possible.

The electric-vehicle propulsion control apparatus 100 according to the first embodiment is suitable for being used with the power converter 6 in which the conversion element 6a is configured from a wide bandgap semiconductor. A wide bandgap semiconductor is a generic term for semiconductors including gallium nitride (GaN), silicon carbide (SiC), and diamond. Because the withstand voltage properties and the allowable current density of the conversion element 6a are increased by using a wide bandgap semiconductor for the conversion element 6a, it is possible to downsize the conversion element 6a and to downsize a semiconductor module incorporating such elements. In addition, because a wide bandgap semiconductor has high heat resistance, it is also possible to downsize the cooler that cools the conversion element 6a.

Using a wide bandgap semiconductor for the conversion element 6a will be a future trend. With the technique according to the first embodiment, because the first reactor 12 can be disposed within the relatively large space in which the power supply cable 14 is installed, it is possible to avoid increasing the size of the housing for the power converter 6. As described above, the technique according to the first embodiment is useful when being used with the power converter 6 in which the conversion element 6a is configured from a wide bandgap semiconductor.

As described above, the electric-vehicle propulsion control apparatus according to the first embodiment includes the first reactor that includes the reactor core having an opening and the winding portion including the filter wire wound around the reactor core. One end of the winding portion of the first reactor is electrically connected to a first cable that is a high-potential-side power supply cable connecting the overhead line and the power converter, and the other end of the winding portion is electrically connected, via the filter circuit, to a second cable that is a low-potential-side power supply cable connecting the rail and the power converter. There is an inductance element between the electrical connection point of the first reactor with the first cable and the overhead line, and the first reactor is configured so as to be magnetically coupled to the inductance element. The winding portion is configured such that the magnetic coupling generates a mutual inductance having a positive value between the power converter and the electrical connection point of the first reactor with the first power supply cable. With this configuration, because a signal in a particular frequency band can be attenuated due to the resonance phenomenon, it is possible to ensure sufficient attenuation of harmonic components in a relatively narrow frequency range in a particular frequency band.

Furthermore, with the electric-vehicle propulsion control apparatus according to the first embodiment, because the mutual inductance M can be generated between the power converter and the electrical connection point of the first reactor with the first power supply cable merely by adding the first reactor, it is possible to ensure attenuation of harmonic components contained in a return current without adding a physical inductance element between the power converter and the filter circuit that is a bypass circuit for noise current.

Moreover, with the electric-vehicle propulsion control apparatus according to the first embodiment, because the first reactor is added to connect an inductance element in series with the filter circuit that is a bypass circuit for noise current, it is possible to make the inductance elements in the filter circuit smaller or reduce the number of inductance elements in the filter circuit, and thus downsize the filter circuit.

Note that, the configuration illustrated in FIG. 1 is an example, and the configuration illustrated in FIG. 2 in which the equivalent circuit is formed is an aspect of the present invention. That is, one aspect of the present invention is a configuration that includes the filter device configured such that the first inductance element L₁, the third inductance element L, and the capacitor element C are connected in series to constitute the series circuit; one end of the series circuit is electrically connected to the low-potential-side power supply cable that connects the rail and the power converter; the other end of the series circuit is electrically connected to the high-potential-side power supply cable that connects the overhead line and the power converter; the second inductance element L₂, which is provided between the electrical connection point of the other end of the series circuit and the overhead line, and the first inductance element L₁ are magnetically coupled to each other; and the magnetic coupling generates the mutual inductance having a positive value between the electrical connection point of the one end of the series circuit and the power converter.

Furthermore, in the equivalent circuit illustrated in FIG. 2, the third inductance element L can be omitted. Thus, another aspect of the present invention is a configuration that includes the filter device configured such that the first inductance element L₁ and the capacitor element C are connected in series to constitute the series circuit; one end of the series circuit is electrically connected to the low-potential-side power supply cable connecting the rail and the power converter; the other end of the series circuit is electrically connected to the high-potential-side power supply cable connecting the overhead line and the power converter; the second inductance element L₂, which is provided between the electrical connection point of the other end of the series circuit and the overhead line, and the first inductance element L₁ are magnetically coupled to each other; and the magnetic coupling generates the mutual inductance having a positive value between the electrical connection point of the one end of the series circuit and the power converter.

### Second Embodiment

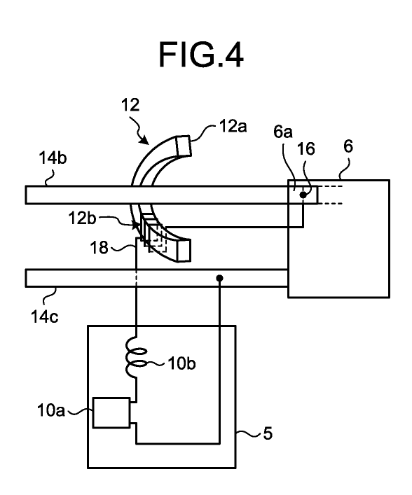

FIG. 4 is a diagram illustrating the configuration of an electric-vehicle propulsion control apparatus according to a second embodiment. In FIG. 4, the electric-vehicle propulsion control apparatus 100 according to the second embodiment is different from the electric-vehicle propulsion control apparatus 100 according to the first embodiment in that the position of the connection point 16 is different. Whereas the connection point 16 is located on the power supply cable 14 that connects the feeder 4a and the power converter 6 in the first embodiment, the connection point 16 is located inside the power converter 6 or at a terminal portion (not illustrated) in the second embodiment. The terminal portion of the power converter 6 in the present embodiment means the portion at which the power supply cable 14 is connected to the power converter 6. That is, the connection point 16 is provided in the power converter 6 in the second embodiment.

Here, the meaning of the connection point 16 being present in the power converter 6 is described. The power converter 6 is a source of noise. For this reason, there are many requests for taking countermeasures against the noise near the noise source. In other words, when the power converter 6 is designed, noise countermeasures are often taken into consideration in customer specifications. If the connection point 16 is located in the power converter 6, the first reactor 12 can be disposed near or inside the power converter 6. That is, by locating the connection point 16 in the power converter 6, there is an advantage in that the degree of freedom in design regarding the arrangement of the first reactor 12 is increased.

By accommodating the first reactor 12 in the power converter 6, it is possible to obtain an effect such that a holding mechanism for holding the first reactor 12 can be manufactured easily.

Furthermore, by locating the connection point 16 at the terminal portion of the power converter 6, it is possible to obtain an effect such that the connection point 16 can be configured without a special connection mechanism in the power supply cable 14.

Note that, the configurations described in the above embodiments are merely examples of the present invention and can be combined with other known techniques, and a part of the configurations can be omitted or changed without departing from the gist of the present invention.

### REFERENCE SIGNS LIST

1 overhead line; 2 rail; 3 current collector; 4a, 4b feeder; 5 filter circuit; 6 power converter; 6a conversion element; 7 motor; 8 wheel; 9 connection cable; 10a capacitor; 10b second reactor; 10A series circuit part; 12 first reactor; 12a reactor core; 12b winding portion; 14 power supply cable; 14a cable first part; 14b cable second part; 16 connection point; 18 filter wire; 100 electric-vehicle propulsion control apparatus.

1. An electric-vehicle propulsion control apparatus comprising:
a filter device; and
a power converter, wherein
the filter device is configured such that:
a first inductance element and a capacitor element are connected in series to constitute a series circuit;
one end of the series circuit is electrically connected to a low-potential-side power supply cable that connects a rail and the power converter;
another end of the series circuit is electrically connected to a high-potential-side power supply cable that connects an overhead line and the power converter; and
a second inductance element, which is provided between an electrical connection point of the another end of the series circuit and the overhead line, and the first inductance element are magnetically coupled to each other, and the magnetic coupling generates a mutual inductance having a positive value between the electrical connection point and the power converter.

2. The electric-vehicle propulsion control apparatus according to claim 1, further comprising a third inductance element connected in series with the first inductance element.

3. An electric-vehicle propulsion control apparatus comprising:
a filter device; and
a power converter, wherein
the filter device comprises:
a filter circuit that includes a capacitor; and
a first reactor that includes a reactor core having an opening and a winding portion including a filter wire wound around the reactor core, and
the winding portion is configured such that:
one end of the winding portion is electrically connected to a high-potential-side power supply cable that connects an overhead line and the power converter;
another end of the winding portion is electrically connected, via the filter circuit, to a low-potential-side power supply cable that connects a rail and the power converter; and
an inductance element, which is provided between an electrical connection point of the one end of the winding portion with the high-potential-side power supply cable and the overhead line, and the first reactor are magnetically coupled to each other, and the magnetic coupling generates a mutual inductance having a positive value between the electrical connection point and the power converter.

4. The electric-vehicle propulsion control apparatus according to claim 3, wherein the filter circuit comprises a second reactor connected in series with the capacitor.

5. The electric-vehicle propulsion control apparatus according to claim 1, wherein the electrical connection point is provided in the power converter.

6. The electric-vehicle propulsion control apparatus according to claim 1, wherein a conversion element constituting the power converter is configured from a wide bandgap semiconductor.

7. The electric-vehicle propulsion control apparatus according to claim 6, wherein the wide bandgap semiconductor is gallium nitride, silicon carbide, or diamond.

8. The electric-vehicle propulsion control apparatus according to claim 3, wherein the electrical connection point is provided in the power converter.

9. The electric-vehicle propulsion control apparatus according to claim 3, wherein a conversion element constituting the power converter is configured from a wide bandgap semiconductor.

10. The electric-vehicle propulsion control apparatus according to claim 9, wherein the wide bandgap semiconductor is gallium nitride, silicon carbide, or diamond.
